(19) United States
(12) Patent Application Publication
(10) Pub. No.: US 2022/0140814 A1
(43) Pub. Date: May 5, 2022

(54) TRANSVERSELY-EXCITED FILM BULK ACOUSTIC RESONATORS WITH INTEGRATED PASSIVE DEVICE

(71) Applicant: Resonant Inc., Austin, TX (US)

(72) Inventors: Greg Dyer, Santa Barbara, CA (US); Jim Costa, Lompoc, CA (US); Andrew Guyette, San Mateo, CA (US); Neal Fenzi, Santa Barbara, CA (US)

(21) Appl. No.: 17/235,243

(22) Filed: Apr. 20, 2021

Related U.S. Application Data
(60) Provisional application No. 63/108,227, filed on Oct. 30, 2020.

(51) Int. Cl. H03H 9/205; H03H 9/02; H03H 9/54; H03H 3/02

(52) U.S. Cl. CPC H03H 9/205; H03H 9/02015; H03H 3/02; H03H 9/542; H03H 9/02228

(57) ABSTRACT

Acoustic resonator devices, filter devices, and methods of making acoustic resonator devices and filter devices. An acoustic resonator device includes a piezoelectric plate, wherein a portion of the piezoelectric plate forms a diaphragm that spans a cavity. An interdigital transducer (IDT) is formed on a front surface of the piezoelectric plate such that interleaved fingers of the IDT are disposed on the diaphragm. An integrated passive device circuit (IPD) is connected to the IDT.

### RELATED APPLICATION INFORMATION

This patent claims priority from provisional patent application 63/108,227, filed Oct. 30, 2020, entitled XBAR INTEGRATED WITH IPD CIRCUIT. The entire content of application 63/108,227 is incorporated herein by reference.

This application is related to patent application Ser. No. 17/133,849, filed Dec. 24, 2020, entitled TRANSVERSELY-EXCITED FILM BULK ACOUSTIC RESONATOR MATRIX FILTERS.

### NOTICE OF COPYRIGHTS AND TRADE DRESS

A portion of the disclosure of this patent document contains material which is subject to copyright protection. This patent document may show and/or describe matter which is or may become trade dress of the owner. The copyright and trade dress owner has no objection to the facsimile reproduction by anyone of the patent disclosure as it appears in the Patent and Trademark Office patent files or records, but otherwise reserves all copyright and trade dress rights whatsoever.

### BACKGROUND

### Field

This disclosure relates to radio frequency filters using acoustic wave resonators, and specifically to filters for use in communications equipment.

### Description of the Related Art

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “pass-band” of the filter. The range of frequencies stopped by such a filter is referred to as the “stop-band” of the filter. A typical RF filter has at least one pass-band and at least one stop-band. Specific requirements on a pass-band or stop-band depend on the specific application. For example, a “pass-band” may be defined as a frequency range where the insertion loss of a filter is better than a defined value such as 1 dB, 2 dB, or 3 dB. A “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front-ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

RF filters typically require many design trade-offs to achieve, for each specific application, the best compromise between performance parameters such as insertion loss, rejection, isolation, power handling, linearity, size and cost. Specific design and manufacturing methods and enhancements can benefit simultaneously one or several of these requirements.

Performance enhancements to the RF filters in a wireless system can have broad impact to system performance. Improvements in RF filters can be leveraged to provide system performance improvements such as larger cell size, longer battery life, higher data rates, greater network capacity, lower cost, enhanced security, higher reliability, etc. These improvements can be realized at many levels of the wireless system both separately and in combination, for example at the RF module, RF transceiver, mobile or fixed sub-system, or network levels.

High performance RF filters for present communication systems commonly incorporate acoustic wave resonators including surface acoustic wave (SAW) resonators, bulk acoustic wave (BAW) resonators, film bulk acoustic wave resonators (FBAR), and other types of acoustic resonators. However, these existing technologies are not well-suited for use at the higher frequencies and bandwidths proposed for future communications networks.

The desire for wider communication channel bandwidths will inevitably lead to the use of higher frequency communications bands. Radio access technology for mobile telephone networks has been standardized by the 3GPP (3^{rd} Generation Partnership Project). Radio access technology for 5^{th} generation mobile networks is defined in the 5G NR (new radio) standard. The 5G NR standard defines several new communications bands. Two of these new communications bands are n77, which uses the frequency range from 3300 MHz to 4200 MHz, and n79, which uses the frequency range from 4400 MHz to 5000 MHz. Both band n77 and band n79 use time-division duplexing (TDD), such that a communications device operating in band n77 and/or band n79 use the same frequencies for both uplink and downlink transmissions. Bandpass filters for bands n77 and n79 must be capable of handling the transmit power of the communications device. WiFi bands at 5 GHz and 6 GHz also require high frequency and wide bandwidth. The 5G NR standard also defines millimeter wave communication bands with frequencies between 24.25 GHz and 40 GHz.

The Transversely-Excited Film Bulk Acoustic Resonator (XBAR) is an acoustic resonator structure for use in microwave filters. The XBAR is described in U.S. Pat. No. 10,491,291, titled TRANSVERSELY EXCITED FILM BULK ACOUSTIC RESONATOR. An XBAR resonator comprises an interdigital transducer (IDT) formed on a thin floating layer, or diaphragm, of a single-crystal piezoelectric material. The IDT includes a first set of parallel fingers, extending from a first busbar and a second set of parallel fingers extending from a second busbar. The first and second sets of parallel fingers are interleaved. A microwave signal applied to the IDT excites a shear primary acoustic wave in the piezoelectric diaphragm. XBAR resonators provide very high electromechanical coupling and high frequency capability. XBAR resonators may be used in a variety of RF filters including band-reject filters, band-pass filters, duplexers, and multiplexers. XBARs are well suited for use in filters for communications bands with frequencies above 3 GHz. Matrix XBAR filters are also suited for frequencies between 1 GHz and 3 GHz.

### DESCRIPTION OF THE DRAWINGS

FIG. 1 includes a schematic plan view, two schematic cross-sectional views, and a detailed cross-sectional view of a transversely-excited film bulk acoustic resonator (XBAR).

FIG. 2A is an equivalent circuit model of an acoustic resonator.

FIG. 2B is a graph of the admittance of an ideal acoustic resonator.

FIG. 2C is a circuit symbol for an acoustic resonator.

FIG. 3A is a schematic diagram of a matrix filter using acoustic resonators.

FIG. 3B is a schematic diagram of a sub-filter of FIG. 3A.

FIG. 4 is a schematic diagram of a matrix filter using XBARs.

FIG. 5 is a schematic cross-sectional view of an XBAR filter device mounted on an integrated passive device (IPD).

FIG. 6 is a schematic plan view of an XBAR filter device connected to an IPD on a circuit board.

FIG. 7 is a schematic cross-sectional view of an XBAR filter device integrated with an IPD.

FIG. 8 is flow chart of a process for making a filter implementing XBARs mounted on an IPD.

FIG. 9 is flow chart of a process for making a filter implementing XBARs connected to an IPD.

FIG. 10 is flow chart of a process for making a filter implementing XBARs integrated with an IPD.

Throughout this description, elements appearing in figures are assigned three-digit or four-digit reference designators, where the two least significant digits are specific to the element and the one or two most significant digit is the figure number where the element is first introduced. An element that is not described in conjunction with a figure may be presumed to have the same characteristics and function as a previously-described element having the same reference designator.

### DETAILED DESCRIPTION

Description of Apparatus

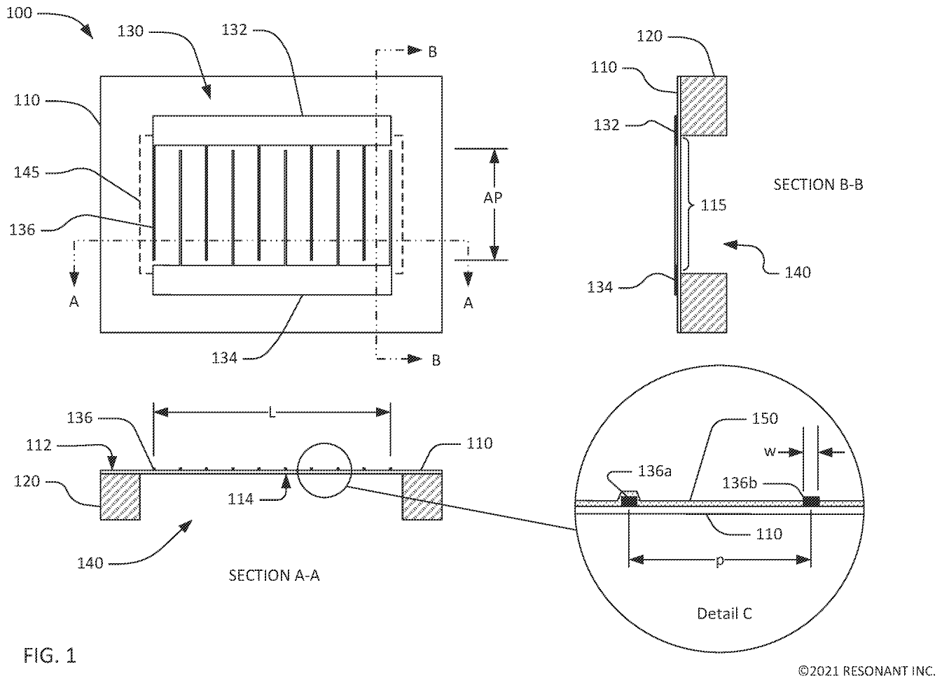

FIG. 1 shows a simplified schematic top view, orthogonal cross-sectional views, and a detailed cross-sectional view of a transversely-excited film bulk acoustic resonator (XBAR) 100. XBAR resonators such as the resonator 100 may be used in a variety of RF filters including band-reject filters, band-pass filters, duplexers, and multiplexers. XBARs are particularly suited for use in filters for communications bands with frequencies above 3 GHz. The matrix XBAR filters described in this patent are also suited for frequencies above 1 GHz.

The XBAR 100 is made up of a thin film conductor pattern formed on a surface of a piezoelectric plate 110 having substantially parallel front and back surfaces 112, 114, respectively. The piezoelectric plate is a thin single-crystal layer of a piezoelectric material such as lithium niobate, lithium tantalate, lanthanum gallium silicate, gallium nitride, or aluminum nitride. The piezoelectric plate is cut such that the orientation of the X, Y, and Z crystalline axes with respect to the front and back surfaces is known and consistent. The piezoelectric plate may be Z-cut (which is to say the Z axis is normal to the front and back surfaces 112, 114), rotated Z-cut, or rotated YX cut. XBARs may be fabricated on piezoelectric plates with other crystallographic orientations.

The back surface 114 of the piezoelectric plate 110 is attached to a surface of the substrate 120 except for a portion of the piezoelectric plate 110 that forms a diaphragm 115 spanning a cavity 140 formed in the substrate. The portion of the piezoelectric plate that spans the cavity is referred to herein as the “diaphragm” 115 due to its physical resemblance to the diaphragm of a microphone. As shown in FIG. 1, the diaphragm 115 is contiguous with the rest of the piezoelectric plate 110 around all of a perimeter 145 of the cavity 140. In this context, “contiguous” means “continuously connected without any intervening item”. In other configurations, the diaphragm 115 may be contiguous with the piezoelectric plate around at least 50% of the perimeter 145 of the cavity 140.

The substrate 120 provides mechanical support to the piezoelectric plate 110. The substrate 120 may be, for example, silicon, sapphire, quartz, or some other material or combination of materials. The back surface 114 of the piezoelectric plate 110 may be bonded to the substrate 120 using a wafer bonding process. Alternatively, the piezoelectric plate 110 may be grown on the substrate 120 or attached to the substrate in some other manner. The piezoelectric plate 110 may be attached directly to the substrate or may be attached to the substrate 120 via one or more intermediate material layers (not shown in FIG. 1).

“Cavity” has its conventional meaning of “an empty space within a solid body.” The cavity 140 may be a hole completely through the substrate 120 (as shown in Section A-A and Section B-B) or a recess in the substrate 120 under the diaphragm 115. The cavity 140 may be formed, for example, by selective etching of the substrate 120 before or after the piezoelectric plate 110 and the substrate 120 are attached.

The conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The first and second pluralities of parallel fingers are interleaved. The interleaved fingers overlap for a distance AP, commonly referred to as the “aperture” of the IDT. The center-to-center distance L between the outermost fingers of the IDT 130 is the “length” of the IDT.

The first and second busbars 132, 134 serve as the terminals of the XBAR 100. A radio frequency or microwave signal applied between the two busbars 132, 134 of the IDT 130 excites a primary acoustic mode within the piezoelectric plate 110. The primary acoustic mode of an XBAR is a bulk shear mode where acoustic energy propagates along a direction substantially orthogonal to the surface of the piezoelectric plate 110, which is also normal, or transverse, to the direction of the electric field created by the IDT fingers. Thus, the XBAR is considered a transversely-excited film bulk wave resonator.

The IDT 130 is positioned on the piezoelectric plate 110 such that at least the fingers of the IDT 130 are disposed on the diaphragm 115 of the piezoelectric plate which spans, or is suspended over, the cavity 140. As shown in FIG. 1, the cavity 140 has a rectangular shape with an extent greater than the aperture AP and length L of the IDT 130. A cavity of an XBAR may have a different shape, such as a regular or irregular polygon. The cavity of an XBAR may have more or fewer than four sides, which may be straight or curved.

The detailed cross-section view (Detail C) shows two IDT fingers 136a, 136b on the surface of the piezoelectric plate 110. The dimension p is the “pitch” of the IDT and the dimension w is the width or “mark” of the IDT fingers. A dielectric layer 150 may be formed between and optionally over (see IDT finger 136a) the IDT fingers. The dielectric layer 150 may be a non-piezoelectric dielectric material, such as silicon dioxide or silicon nitride. The dielectric layer 150 may be formed of multiple layers of two or more materials. The IDT fingers 136a and 136b may be aluminum, copper, beryllium, gold, tungsten, molybdenum, alloys and combinations thereof, or some other conductive material. Thin (relative to the total thickness of the conductors) layers of other metals, such as chromium or titanium, may be formed under and/or over and/or as layers within the fingers to improve adhesion between the fingers and the piezoelectric plate 110 and/or to passivate or encapsulate the fingers and/or to improve power handling. The busbars of the IDT 130 may be made of the same or different materials as the fingers.

For ease of presentation in FIG. 1, the geometric pitch and width of the IDT fingers is greatly exaggerated with respect to the length (dimension L) and aperture (dimension AP) of the XBAR. A typical XBAR has more than ten parallel fingers in the IDT 110. An XBAR may have hundreds of parallel fingers in the IDT 110. Similarly, the thickness of the fingers in the cross-sectional views is greatly exaggerated.

An XBAR based on shear acoustic wave resonances can achieve better performance than current state-of-the art surface acoustic wave (SAW), film-bulk-acoustic-resonators (FBAR), and solidly-mounted-resonator bulk-acoustic-wave (SMR BAW) devices. In particular, the piezoelectric coupling for shear wave XBAR resonances can be high (>20%) compared to other acoustic resonators. High piezoelectric coupling enables the design and implementation of microwave and millimeter-wave filters of various types with appreciable bandwidth.

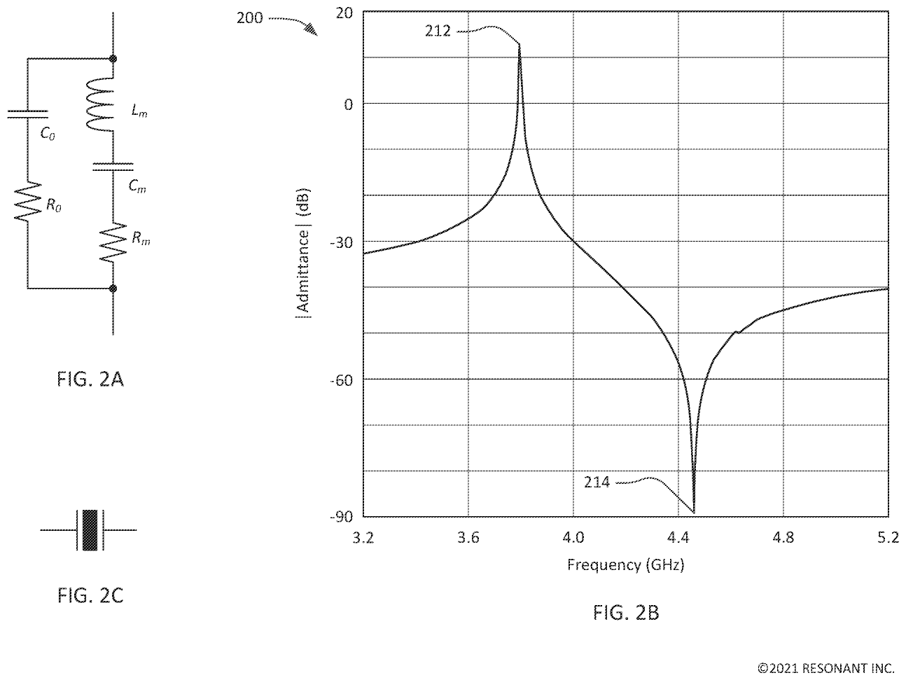

The basic behavior of acoustic resonators, including XBARs, is commonly described using the Butterworth Van Dyke (BVD) circuit model as shown in FIG. 2A. The BVD circuit model consists of a motional arm and a static arm. The motional arm includes a motional inductance Lₘ, a motional capacitance Cₘ, and a resistance Rₘ. The static arm includes a static capacitance C₀ and a resistance R₀. While the BVD model does not fully describe the behavior of an acoustic resonator, it does a good job of modeling the two primary resonances that are used to design band-pass filters, duplexers, and multiplexers (multiplexers are filters with more than 2 input or output ports with multiple passbands).

The first primary resonance of the BVD model is the motional resonance caused by the series combination of the motional inductance Lₘ and the motional capacitance Cₘ. The second primary resonance of the BVD model is the anti-resonance caused by the combination of the motional inductance Lₘ, the motional capacitance Cₘ, and the static capacitance C₀. In a lossless resonator (Rₘ=R₀=0), the frequency Fᵣ of the motional resonance is given by

$${F}_{r} = \frac{1}{2 π \sqrt{{L}_{m} {C}_{m}}} \qquad ( 1 )$$

The frequency Fₐ of the anti-resonance is given by

$${F}_{a} = {F}_{r} \sqrt{1 + \frac{1}{γ}} \qquad ( 2 )$$

where γ=C₀/Cₘ is dependent on the resonator structure and the type and the orientation of the crystalline axes of the piezoelectric material.

FIG. 2B is a graph 200 of the magnitude of admittance of a theoretical lossless acoustic resonator. The acoustic resonator has a resonance 212 at a resonance frequency where the admittance of the resonator approaches infinity. The resonance is due to the series combination of the motional inductance Lₘ and the motional capacitance Cₘ in the BVD model of FIG. 2A. The acoustic resonator also exhibits an anti-resonance 214 where the admittance of the resonator approaches zero. The anti-resonance is caused by the combination of the motional inductance Lₘ, the motional capacitance Cₘ, and the static capacitance C₀. In a lossless resonator (Rₘ=R₀=0), the frequency Fᵣ of the resonance is given by

$${F}_{r} = \frac{1}{2 π \sqrt{{L}_{m} {C}_{m}}} \qquad ( 1 )$$

The frequency Fₐ of the anti-resonance is given by

$${F}_{a} = {F}_{r} \sqrt{1 + \frac{1}{γ}} \qquad ( 2 )$$

In over-simplified terms, the lossless acoustic resonator can be considered a short circuit at the resonance frequency 212 and an open circuit at the anti-resonance frequency 214. The resonance and anti-resonance frequencies in FIG. 2B are representative, and an acoustic resonator may be designed for other frequencies.

FIG. 2C shows the circuit symbol for an acoustic resonator such as an XBAR. This symbol will be used to designate each acoustic resonator in schematic diagrams of filters in subsequent figures.

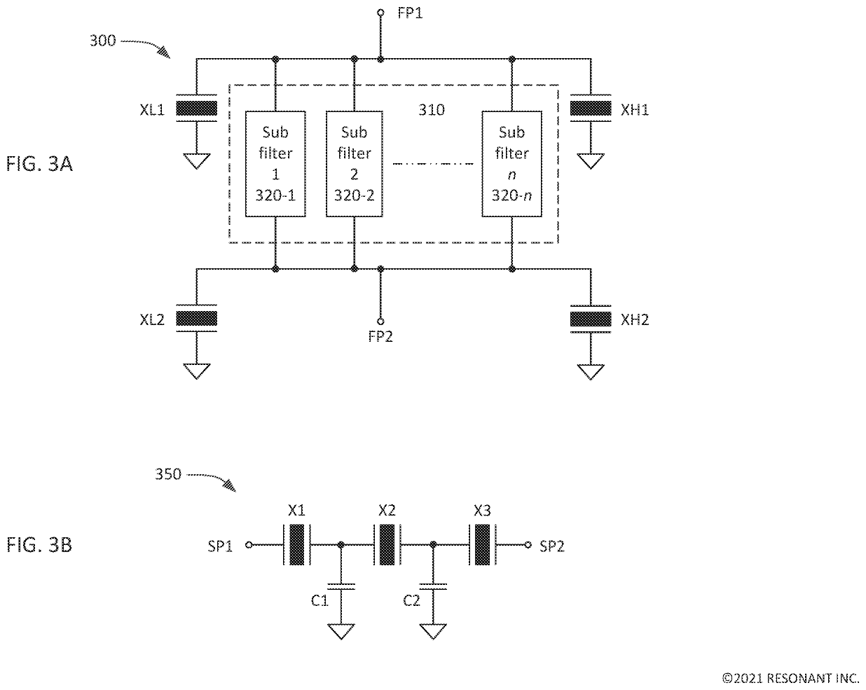

FIG. 3A is a schematic diagram of a matrix filter 300 using acoustic resonators. The matrix filter 300 includes an array 310 of n sub-filters 320-1, 320-2, 320-n connected in parallel between a first filter port (FP1) and a second filter port (FP2), where n is an integer greater than one. Each of the n sub-filters 320-1, 320-2, 320-n is a bandpass filter having a bandwidth about 1/n times the bandwidth of the matrix filter 300. The sub-filters 320-1, 320-2, 320-n have contiguous passbands such that the bandwidth of the matrix filter 300 is equal to the sum of the bandwidths of the constituent sub-filters. In the subsequent examples in this patent n=3. n can be less than or greater than 3 as necessary to provide the desired bandwidth for the matrix filter 300.

The array 310 of sub-filters is terminated at both ends by acoustic resonators XL1, XL2, XH1, and XH2, which are preferably but not necessarily XBARs. The acoustic resonators XL1, XL2, XH1, and XH2 create “transmission zeros” at their respective resonance frequencies. A “transmission zero” is a frequency where the input-output transfer function of the filter is very low (and would be zero if the acoustic resonators XL1, XL2, XH1, and XH2 were lossless). Typically, but not necessarily, the resonance frequencies of XL1 and XL2 are equal, and the resonance frequencies of XH1 and XH2 are equal. The resonant frequencies of the acoustic resonators XL1, XL2 are selected to provide transmission zeros adjacent to the lower edge of the filter passband. XL1 and XL2 may be referred to as “low-edge resonators” since their resonant frequencies are proximate the lower edge of the filter passband. The acoustic resonators XL1 and XL2 also act as shunt inductances to help match the impedance at the ports of the filter to a desired impedance value. In the subsequent examples in this patent, the impedance at all ports of the filters is matched to 50 ohms. The resonant frequencies of acoustic resonators XH1, XH2 are selected to provide transmission zeros at or above the higher edge of the filter passband. XH1 and XH2 may be referred to as “high-edge resonators” since their resonant frequencies are proximate the higher edge of the filter passband. High-edge resonators XH1 and XH2 may not be required in all matrix filters.

FIG. 3B is a schematic diagram of a sub-filter 350 suitable for sub-filters 320-1, 320-2, and 320-n. The sub-filter 350 includes three acoustic resonators XA, XB, XC connected in series between a first sub-filter port (SP1) and a second sub-filter port (SP2). The acoustic resonators X1, X2, X3 are preferably but not necessarily XBARs. The sub-filter 350 includes two coupling capacitors CA, CB, each of which is connected between ground and a respective node between two of the acoustic resonators. The inclusion of three acoustic resonators in the sub-filter 350 is exemplary. A sub-filter may have m acoustic resonators, where m is an integer greater than one. A sub-filter with m acoustic resonators includes m−1 coupling capacitors. The in acoustic resonators of a sub-filter are connected in series between the two ports SP1 and SP2 of a sub-filter and each of the n−1 coupling capacitors is connected between ground and a node between a respective pair of acoustic resonators from the in acoustic resonators.

Compared to other types of acoustic resonators, XBARs have very high electromechanical coupling (which results in a large difference between the resonance and anti-resonance frequencies), but low capacitance per unit area. The matrix filter architecture, as shown in FIG. 3A and FIG. 3B, takes advantage of the high electromechanical coupling of XBARs without requiring high resonator capacitance.

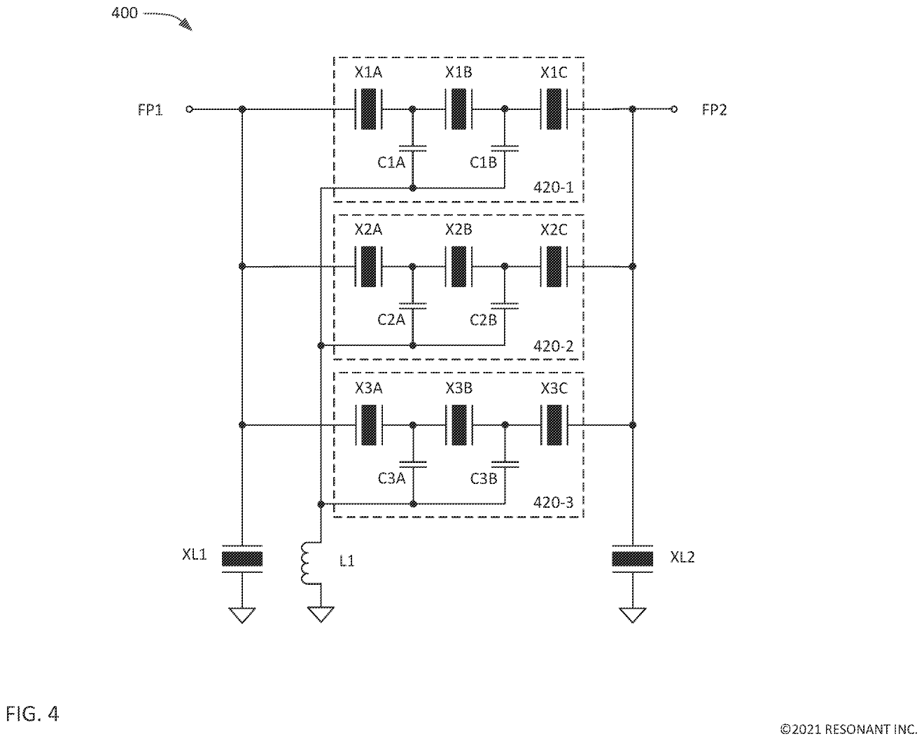

FIG. 4 is a schematic circuit diagram of an exemplary matrix filter 400 implemented with XBARs. The matrix filter 400 includes three sub-filters 420-1, 420-2, 420-3 connected in parallel between a first filter port (FP1) and a second filter port (FP2). The sub-filters 420-1, 420-2, 420-3 have contiguous passbands such that the bandwidth of the matrix filter 300 is equal to the sum of the bandwidths of the constituent sub-filters. Each sub-filter includes three XBARs connected in series and two capacitors. For example, sub-filter 420-1 includes XBARs X1A, X1B, X1C and capacitors C1A, C1B. Components of the other sub-filters 420-2 and 420-3 are similarly identified. Low-edge XBARs XL1 and XL2 are connected between FP1 and FP2, respectively, and ground. All of the capacitors within the sub-filters are connected to ground through a common inductor L1. The inclusion of the inductor L1 improves the out-of-band rejection of the matrix filter 400. The matrix filter 400 does not include high-edge resonators.

The exemplary matrix filter 400 is symmetrical in that the impedances at FP1 and FP2 are both equal to 50 ohms. The internal circuitry of the filter is also symmetrical, with XBARs X_A and X_C within each sub-filter being the same and low-edge resonators XL1 and XL2 being the same. Other matrix filters may be designed to have significantly different impedances at FP1 and FP2, in which event the internal circuitry will not be symmetrical.

Filters implemented with acoustic resonators, including filters implemented with XBARs like those shown in FIGS. 3A, 3B, and 4, typically are integrated with a carrier, such as a printed circuit board (PCB) or a high temperature cofired ceramic (HTCC) circuit. However, HTCC circuits are limited to relatively simple RF designs compared to the current state of the art. Further, PCBs have degraded thermal transport as their RF designs become more complex. Both HTCC circuits and PCBs have limited Q for integrated components.

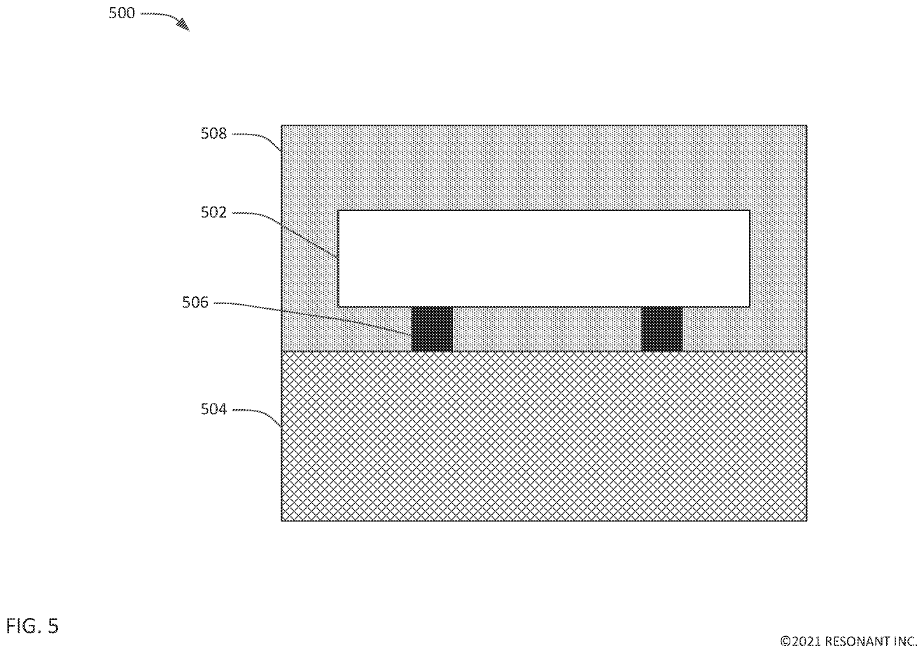

FIG. 5 is a schematic cross-sectional view of a device 500 with a filter 502 implementing one or more XBARs mounted on an integrated passive device (IPD) 504. The filter 502 is electrically coupled to the IPD 504 via conductors 506, for example, solderballs, gold bumps, or plated vias. The IPD 504 can be any suitable IPD, such as IPD formed of a Si dielectric material with Cu traces, with electronic components being integrated into the same package. An overmold 508, or a form-fitting lid or cap, can seal the filter 502 to the IPD 504 to protect and insulate the device. The overmold could be plated for electromagnetic interference (EMI) reduction.

IPDs have lower parasitic modes, higher Q routing and inductors, and superior thermal transport, as compared with PCBs and HTCC circuits, such that an XBAR mounted on an IPD can provide superior RF and thermal architecture for advanced, high power acoustic filters. An IPD as a carrier for the XBAR can provide 10 to 100 times better heat sinking than a PCB or HTCC circuit, and the capability to design complex RF circuits for high isolation and rejection applications.

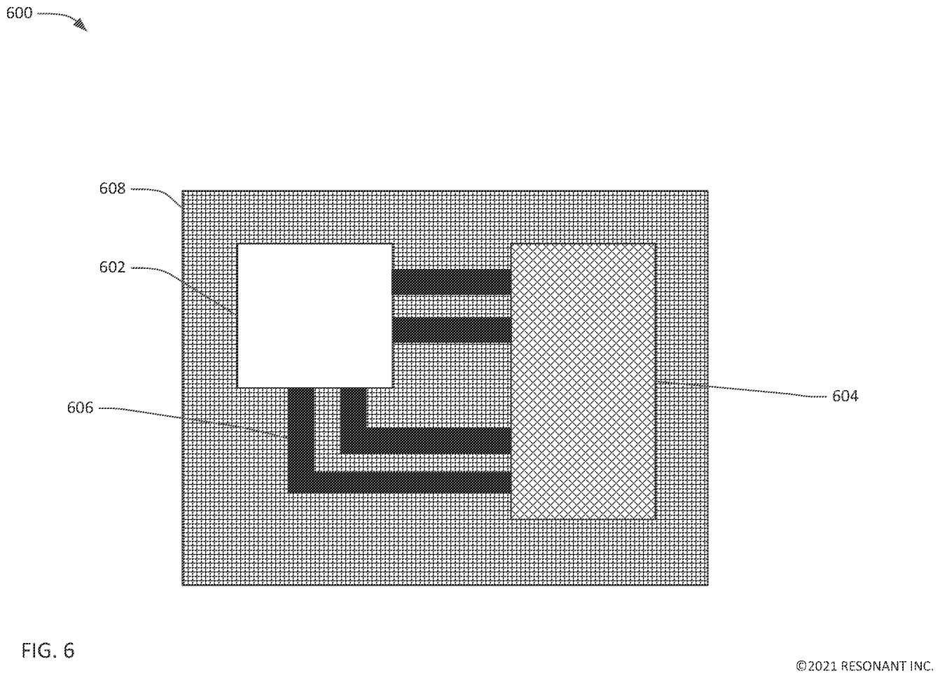

FIG. 6 is a schematic plan view of a device 600 with a filter 602 implementing one or more XBARs connected to an adjacent IPD 604 on a circuit board 608, which could be part of a higher order circuit or functional module. The filter 602 is electrically coupled to the IPD via conductors 606, for example, solderballs, gold bumps, plated vias, circuit board traces or bond wires. Connecting a filter implementing XBARs to an adjacent IPD on a circuit board also provides higher Q routing and inductors, as compared to HTCC circuits and PCBs, for matching network and RF design. An overmold or lid (not shown) could also be disposed over the device 600 for protection and insulation. Thus, complex RF circuits for high isolation and rejection applications can be designed with the IPD.

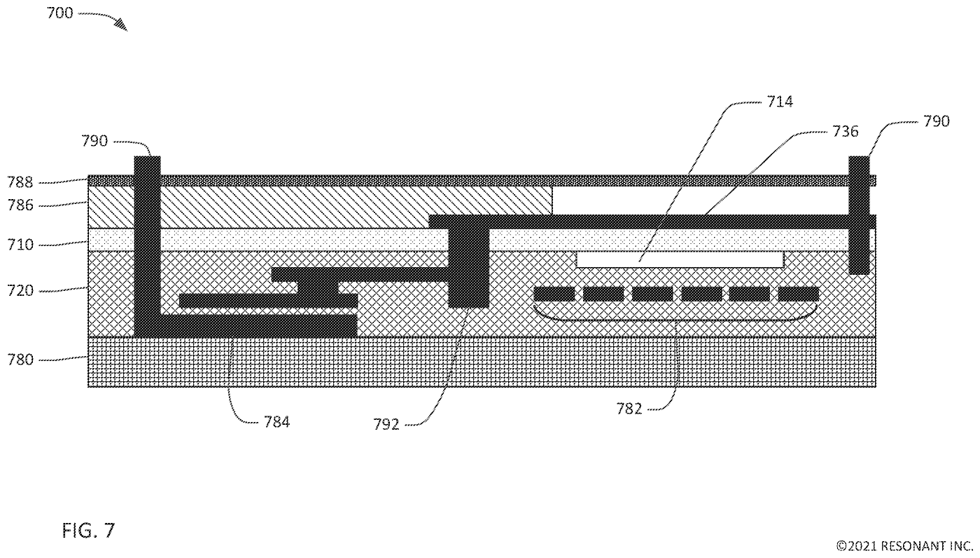

FIG. 7 is a schematic cross-sectional view of a device 700 with an IPD integrated into an XBAR wafer-level packaging (WLP) structure. An IPD layer 720 is mounted on a Si base wafer 780 (or die). The IPD layer 720 has embedded electronic devices. For example, the IPD layer 720 can be formed of SiO₂ with imbedded Cu traces forming electronic devices such as an IPD metal-insulator-metal (MIM) capacitor 784 and an IPD spiral inductor 782. The MIM capacitor 784 may be, for example, any of the capacitors of the exemplary matrix filter 400 of FIG. 4. The spiral inductor 782 may be, for example, the inductor L1 of the exemplary matrix filter 400. A cavity 714 is formed in the IPD layer 720. The circuits and other electronic elements in the device 700 could be formed by alternately layering SiO₂ and metal traces on a silicon base layer.

A piezoelectric plate 710, as described with respect to FIG. 1, is bonded on the IPD layer 720 after the electronic devices are constructed, such that a portion of the piezoelectric plate 710 is above the cavity 714 formed in the IPD layer. For ease of representation, the cavity 714 is shown in FIG. 7 above the IPD spiral inductor 782. The cavity 714 is not necessarily over or adjacent to any of the components formed in the IPD layer 720. The cavity 714 may be formed prior to bonding the piezoelectric plate 710 to the IPD layer 720. Alternatively, the cavity 714 may be formed after bonding the piezoelectric plate 710 to the IPD layer 720. For example, the cavity 714 may be formed using an etchant introduce through holes (not shown) in the piezoelectric plate 710.

An IDT 736, as described with respect to FIG. 1, is formed on the portion of the piezoelectric plate 710 that is above the cavity 714. The IDT 736 may be connected to one or more components in the IPD layer 720 by one or more conductive vias. In the example of FIG. 7, the IDT 736 is connected to MIM capacitor 784 by conductive via 792.

A lid 788 can be disposed on structural supports such as a rib 786 to seal and insulate the device 700. The lid 788 and the rib 736 can be formed of any suitable material, such as layers of polyimide. An overmold could also be disposed over the device 700 for protection and insulation. WLP structures can be made of laminates of layers of photosensitive polyimide. One layer is photo-etched to form walls and a thicker top lid layer can cover the entire device. Contacts can be made with plated holes through the walls and lid or edge plating that climbs the edge of the outside wall to wrap onto the lid and form contacts. Traces and metalization can also be on the top lid surface for shielding or connecting contacts. The lid can be thicker to resist overmold pressure which would otherwise collapse the lid onto the circuitry and affect the device response. Tall vias 792 can be plated contacts from the base wafer going through the walls and lid to form external contacts. Exemplary dimensions of the tall vias 792 can be about 70 um tall and 60-80 um wide.

IPD integrated into an XBAR wafer-level packaging (WLP) structure provides higher Q routing and inductors, as compared to HTCC circuits and PCBs, such that complex RF circuits for high isolation and rejection applications can be designed. An additional benefit of integrating XBAR and IPD structures is very low resistance connections between XBARs can be made using vias and conductors in the IPD layer 720. Further, routing connections in the IPD layer 720 may allow more efficient use of the area of the piezoelectric plate 710.

Description of Methods

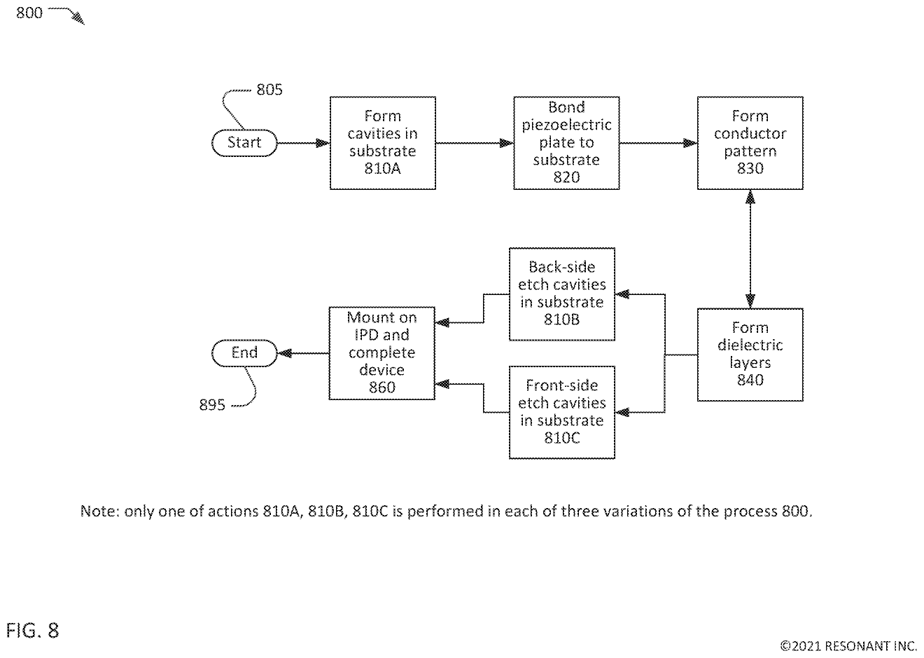

FIG. 8 is a simplified flow chart showing a process 800 for making an XBAR or a filter incorporating XBARs mounted on an IPD. The process 800 starts at 805 with a substrate and a plate of piezoelectric material and ends at 895 with a completed XBAR or filter mounted on an IPD. The flow chart of FIG. 8 includes only major process steps. Various conventional process steps (e.g. surface preparation, cleaning, inspection, baking, annealing, monitoring, testing, etc.) may be performed before, between, after, and during the steps shown in FIG. 8.

The flow chart of FIG. 8 captures three variations of the process 800 for making an XBAR which differ in when and how cavities are formed in the substrate. The cavities may be formed at steps 810A, 810B, or 810C. Only one of these steps is performed in each of the three variations of the process 800.

The piezoelectric plate may be, for example, Z-cut lithium niobate or lithium tantalate with Euler angles θ, 0, 90°. The piezoelectric plate may be rotated Z-cut lithium niobate with Euler angles θ, β, 90°, where β is in the range from −15° to +5°. The piezoelectric plate may be rotated Y-cut lithium niobate or lithium tantalate with Euler angles 0, β, 0, where β is in the range from 0 to 60°. The piezoelectric plate may be some other material or crystallographic orientation. The substrate may preferably be silicon. The substrate may be some other material that allows formation of deep cavities by etching or other processing.

In one variation of the process 800, one or more cavities are formed in the substrate at 810A, before the piezoelectric plate is bonded to the substrate at 820. A separate cavity may be formed for each resonator in a filter device. The one or more cavities may be formed using conventional photolithographic and etching techniques. Typically, the cavities formed at 810A will not penetrate through the substrate.

At 820, the piezoelectric plate is bonded to the substrate. The piezoelectric plate and the substrate may be bonded by a wafer bonding process. Typically, the mating surfaces of the substrate and the piezoelectric plate are highly polished. One or more layers of intermediate materials, such as an oxide or metal, may be formed or deposited on the mating surface of one or both of the piezoelectric plate and the substrate. One or both mating surfaces may be activated using, for example, a plasma process. The mating surfaces may then be pressed together with considerable force to establish molecular bonds between the piezoelectric plate and the substrate or intermediate material layers.

A conductor pattern, including IDTs of each XBAR, is formed at 830 by depositing and patterning two or more conductor levels on the front side of the piezoelectric plate. The conductor levels typically include a first conductor level that includes the IDT fingers, and a second conductor level formed over the IDT busbars and other conductors except the IDT fingers. In some devices, a third conductor levels may be formed on the contact pads. Each conductor level may be one or more layers of, for example, aluminum, an aluminum alloy, copper, a copper alloy, or some other conductive metal. Optionally, one or more layers of other materials may be disposed below (i.e. between each conductor layer and the piezoelectric plate) and/or on top of each conductor layer. For example, a thin film of titanium, chrome, or other metal may be used to improve the adhesion between the first conductor level and the piezoelectric plate. The second conductor level may be a conduction enhancement layer of gold, aluminum, copper or other higher conductivity metal may be formed over portions of the first conductor level (for example the IDT bus bars and interconnections between the IDTs).

Each conductor level may be formed at 830 by depositing the appropriate conductor layers in sequence over the surface of the piezoelectric plate. The excess metal may then be removed by etching through patterned photoresist. The conductor level can be etched, for example, by plasma etching, reactive ion etching, wet chemical etching, and other etching techniques.

Alternatively, each conductor level may be formed at 830 using a lift-off process. Photoresist may be deposited over the piezoelectric plate. and patterned to define the conductor level. The appropriate conductor layers may be deposited in sequence over the surface of the piezoelectric plate. The photoresist may then be removed, which removes the excess material, leaving the conductor level.

When a conductor level has multiple layers, the layers may be deposited and patterned separately. In particular, different patterning processes (i.e. etching or lift-off) may be used on different layers and/or levels and different masks are required where two or more layers of the same conductor level have different widths or shapes.

At 840, dielectric layers may be formed by depositing one or more layers of dielectric material on the front side of the piezoelectric plate. As previously described, the dielectric layers may include a different dielectric thickness over the IDT fingers of the XBARs within each sub-filter. Each dielectric layer may be deposited using a conventional deposition technique such as sputtering, evaporation, or chemical vapor deposition. Each dielectric layer may be deposited over the entire surface of the piezoelectric plate, including on top of the conductor pattern. Alternatively, one or more lithography processes (using photomasks) may be used to limit the deposition of the dielectric layers to selected areas of the piezoelectric plate, such as only between the interleaved fingers of the IDTs. Masks may also be used to allow deposition of different thicknesses of dielectric materials on different portions of the piezoelectric plate.

In a second variation of the process 800, one or more cavities are formed in the back side of the substrate at 810B. A separate cavity may be formed for each resonator in a filter device. The one or more cavities may be formed using an anisotropic or orientation-dependent dry or wet etch to open holes through the back side of the substrate to the piezoelectric plate. In this case, the resulting resonator devices will have a cross-section as shown in FIG. 1.

In a third variation of the process 800, one or more cavities in the form of recesses in the substrate may be formed at 810C by etching the substrate using an etchant introduced through openings in the piezoelectric plate. A separate cavity may be formed for each resonator in a filter device.

In all variations of the process 800, the filter device is mounted on an IPD and completed at 860. The filter device can be mounted on the IPD via conductors, such as gold bumps, solderballs, or wirebonds, according to conventional methods. An overmold can be formed over the filter device to protect and insulate the filter device and to facilitate mounting to the IPD. Overmolding is a process where a single part is created from combining two or more different materials. Typically the substrate is partially or fully covered by the subsequent overmold during manufacturing. Other actions that may occur at 860 include depositing an encapsulation/passivation layer such as SiO₂ or Si₃O₄ over all or a portion of the device; forming bonding pads or solder bumps or other means for making connection between the device and external circuitry; excising individual devices from a wafer containing multiple devices; other packaging steps; and testing. Another action that may occur at 860 is to tune the resonant frequencies of the resonators within the device by adding or removing metal or dielectric material from the front side of the device. After the filter device is completed, the process ends at 895.

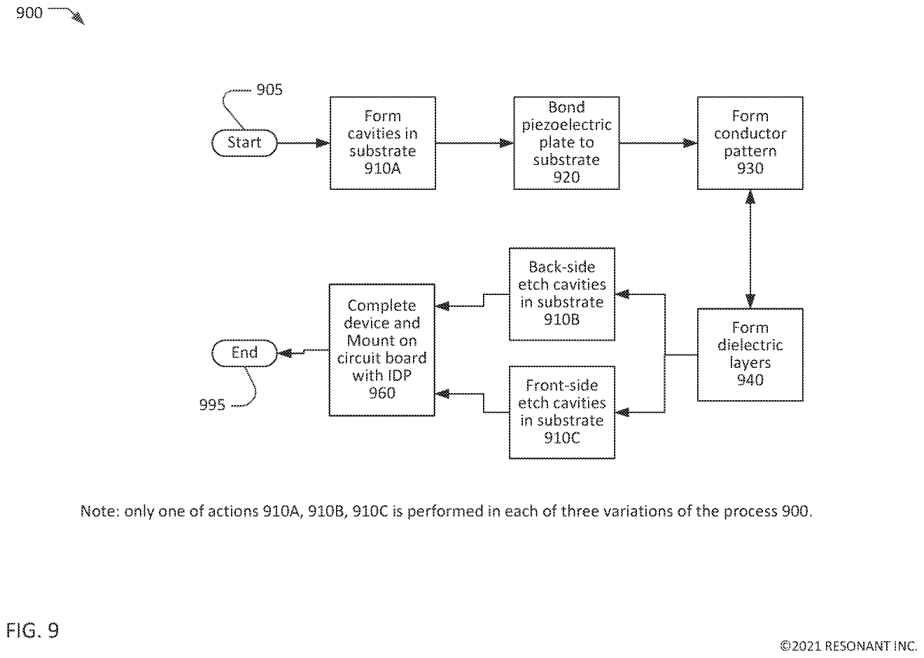

FIG. 9 is simplified flow chart of a process 900 for making a filter implementing XBARs connected to an IPD. The process 900 starts at 905 with a substrate and a plate of piezoelectric material and ends at 995 with a completed XBAR or filter. The flow chart of FIG. 9 includes only major process steps. Various conventional process steps (e.g. surface preparation, cleaning, inspection, baking, annealing, monitoring, testing, etc.) may be performed before, between, after, and during the steps shown in FIG. 9.

The flow chart of FIG. 9 captures three variations of the process 900 for making an XBAR which differ in when and how cavities are formed in the substrate. The cavities may be formed at steps 910A, 910B, or 910C. Only one of these steps is performed in each of the three variations of the process 900.

The piezoelectric plate may be, for example, Z-cut lithium niobate or lithium tantalate with Euler angles 0, 0, 90°. The piezoelectric plate may be rotated Z-cut lithium niobate with Euler angles 0, β, 90°, where β is in the range from −15° to +5°. The piezoelectric plate may be rotated Y-cut lithium niobate or lithium tantalate with Euler angles 0, β, 0, where β is in the range from 0 to 60°. The piezoelectric plate may be some other material or crystallographic orientation. The substrate may preferably be silicon. The substrate may be some other material that allows formation of deep cavities by etching or other processing.

In one variation of the process 900, one or more cavities are formed in the substrate at 910A, before the piezoelectric plate is bonded to the substrate at 920. A separate cavity may be formed for each resonator in a filter device. The one or more cavities may be formed using conventional photolithographic and etching techniques. Typically, the cavities formed at 910A will not penetrate through the substrate.

At 920, the piezoelectric plate is bonded to the substrate. The piezoelectric plate and the substrate may be bonded by a wafer bonding process. Typically, the mating surfaces of the substrate and the piezoelectric plate are highly polished. One or more layers of intermediate materials, such as an oxide or metal, may be formed or deposited on the mating surface of one or both of the piezoelectric plate and the substrate. One or both mating surfaces may be activated using, for example, a plasma process. The mating surfaces may then be pressed together with considerable force to establish molecular bonds between the piezoelectric plate and the substrate or intermediate material layers.

A conductor pattern, including IDTs of each XBAR, is formed at 930 by depositing and patterning two or more conductor levels on the front side of the piezoelectric plate. The conductor levels typically include a first conductor level that includes the IDT fingers, and a second conductor level formed over the IDT busbars and other conductors except the IDT fingers. In some devices, a third conductor levels may be formed on the contact pads. Each conductor level may be one or more layers of, for example, aluminum, an aluminum alloy, copper, a copper alloy, or some other conductive metal. Optionally, one or more layers of other materials may be disposed below (i.e. between each conductor layer and the piezoelectric plate) and/or on top of each conductor layer. For example, a thin film of titanium, chrome, or other metal may be used to improve the adhesion between the first conductor level and the piezoelectric plate. The second conductor level may be conduction enhancement layer of gold, aluminum, copper or other higher conductivity metal may be formed over portions of the first conductor level (for example the IDT bus bars and interconnections between the IDTs).

Each conductor level may be formed at 930 by depositing the appropriate conductor layers in sequence over the surface of the piezoelectric plate. The excess metal may then be removed by etching through patterned photoresist. The conductor level can be etched, for example, by plasma etching, reactive ion etching, wet chemical etching, and other etching techniques.

Alternatively, each conductor level may be formed at 930 using a lift-off process. Photoresist may be deposited over the piezoelectric plate. and patterned to define the conductor level. The appropriate conductor layers may be deposited in sequence over the surface of the piezoelectric plate. The photoresist may then be removed, which removes the excess material, leaving the conductor level.

When a conductor level has multiple layers, the layers may be deposited and patterned separately. In particular, different patterning processes (i.e. etching or lift-off) may be used on different layers and/or levels and different masks are required where two or more layers of the same conductor level have different widths or shapes.

At 940, dielectric layers may be formed by depositing one or more layers of dielectric material on the front side of the piezoelectric plate. As previously described, the dielectric layers may include a different dielectric thickness over the IDT fingers of the XBARs within each sub-filter. Each dielectric layer may be deposited using a conventional deposition technique such as sputtering, evaporation, or chemical vapor deposition. Each dielectric layer may be deposited over the entire surface of the piezoelectric plate, including on top of the conductor pattern. Alternatively, one or more lithography processes (using photomasks) may be used to limit the deposition of the dielectric layers to selected areas of the piezoelectric plate, such as only between the interleaved fingers of the IDTs. Masks may also be used to allow deposition of different thicknesses of dielectric materials on different portions of the piezoelectric plate.

In a second variation of the process 900, one or more cavities are formed in the back side of the substrate at 910B. A separate cavity may be formed for each resonator in a filter device. The one or more cavities may be formed using an anisotropic or orientation-dependent dry or wet etch to open holes through the back side of the substrate to the piezoelectric plate. In this case, the resulting resonator devices will have a cross-section as shown in FIG. 1.

In a third variation of the process 900, one or more cavities in the form of recesses in the substrate may be formed at 910C by etching the substrate using an etchant introduced through openings in the piezoelectric plate. A separate cavity may be formed for each resonator in a filter device.

In all variations of the process 900, the filter device is completed and mounted on a circuit board with an IPD at 960 with electrical connections formed to connect the filter device to the IPD. A WLP structure may be formed over the filter device before it is mounted to the circuit board. Actions that may occur at 960 include depositing an encapsulation/passivation layer such as SiO₂ or Si₃O₄ over all or a portion of the device; forming bonding pads or solder bumps or other means for making connection between the device and external circuitry; excising individual devices from a wafer containing multiple devices; other packaging steps; and testing. Another action that may occur at 960 is to tune the resonant frequencies of the resonators within the device by adding or removing metal or dielectric material from the front side of the device. After the filter device is completed, the process ends at 995.

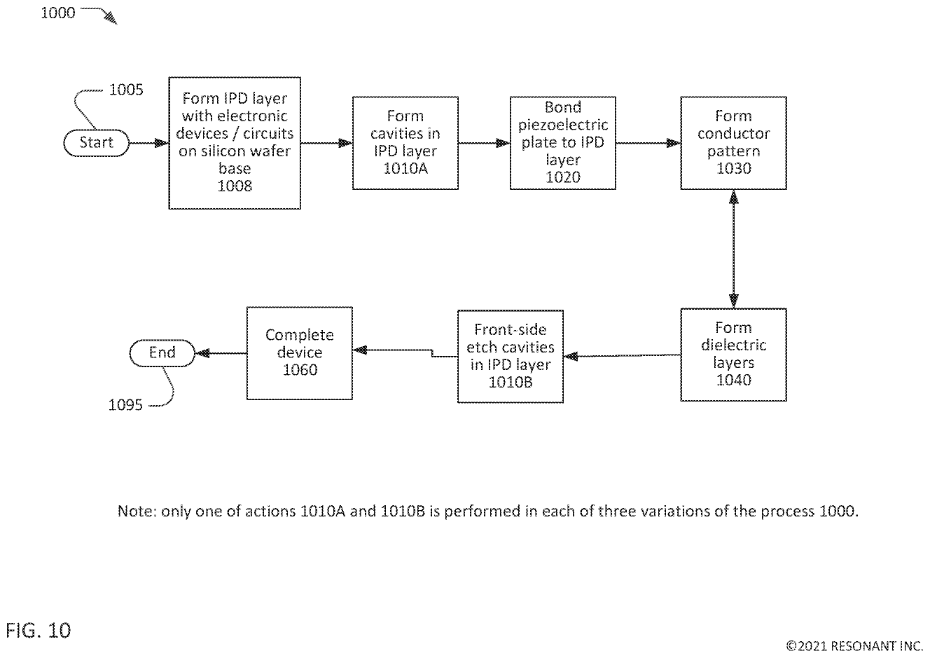

FIG. 10 is a simplified flow chart of a process 1000 for making a filter implementing XBARs integrated with an IPD.

The process 1000 starts at 1005 with a silicon wafer base and a plate of piezoelectric material and ends at 1095 with a completed XBAR or filter integrated with an IPD. The flow chart of FIG. 10 includes only major process steps. Various conventional process steps (e.g. surface preparation, cleaning, inspection, baking, annealing, monitoring, testing, etc.) may be performed before, between, after, and during the steps shown in FIG. 10.

The flow chart of FIG. 10 captures two variations of the process 1000 for making an XBAR which differ in when and how cavities are formed in the substrate. The cavities may be formed at steps 1010A and 1010B. Only one of these steps is performed in each variation of the process 1000.

At step 1008, an IPD layer is formed on the silicon base wafer. The IPD layer is formed of SiO₂ and electronic devices and circuits are formed within the IPD layer. For example, the electronic devices and circuits can be formed by alternately layering SiO₂ and metal circuit on a silicon base layer.

In one variation of the process 1000, one or more cavities are formed in the IPD layer at 1010A, before the piezoelectric plate is bonded to the IPD layer at 820. A separate cavity may be formed for each resonator in a filter device. The one or more cavities may be formed using conventional photolithographic and etching techniques. Typically, the cavities formed at 1010A will not penetrate through the IPD layer.

At 1020, a piezoelectric plate is bonded to the IPD layer. The piezoelectric plate and the IPD layer may be bonded by a wafer bonding process. Typically, the mating surfaces of the IPD layer and the piezoelectric plate are highly polished. One or more layers of intermediate materials, such as an oxide or metal, may be formed or deposited on the mating surface of one or both of the piezoelectric plate and the IPD layer. One or both mating surfaces may be activated using, for example, a plasma process. The mating surfaces may then be pressed together with considerable force to establish molecular bonds between the piezoelectric plate and the substrate or intermediate material layers.

The piezoelectric plate may be, for example, Z-cut lithium niobate or lithium tantalate with Euler angles 0, 0, 90°. The piezoelectric plate may be rotated Z-cut lithium niobate with Euler angles 0, β, 90°, where β is in the range from −15° to +5°. The piezoelectric plate may be rotated Y-cut lithium niobate or lithium tantalate with Euler angles 0, β, 0, where β is in the range from 0 to 60°. The piezoelectric plate may be some other material or crystallographic orientation. The substrate may preferably be silicon. The substrate may be some other material that allows formation of deep cavities by etching or other processing.

A conductor pattern, including IDTs of each XBAR, is formed at 1030 by depositing and patterning two or more conductor levels on the front side of the piezoelectric plate. The conductor levels typically include a first conductor level that includes the IDT fingers, and a second conductor level formed over the IDT busbars and other conductors except the IDT fingers. In some devices, a third conductor levels may be formed on the contact pads. Each conductor level may be one or more layers of, for example, aluminum, an aluminum alloy, copper, a copper alloy, or some other conductive metal. Optionally, one or more layers of other materials may be disposed below (i.e. between each conductor layer and the piezoelectric plate) and/or on top of each conductor layer. For example, a thin film of titanium, chrome, or other metal may be used to improve the adhesion between the first conductor level and the piezoelectric plate. The second conductor level may be conduction enhancement layer of gold, aluminum, copper or other higher conductivity metal may be formed over portions of the first conductor level (for example the IDT bus bars and interconnections between the IDTs).

Each conductor level may be formed at 1030 by depositing the appropriate conductor layers in sequence over the surface of the piezoelectric plate. The excess metal may then be removed by etching through patterned photoresist. The conductor level can be etched, for example, by plasma etching, reactive ion etching, wet chemical etching, and other etching techniques.

Alternatively, each conductor level may be formed at 1030 using a lift-off process. Photoresist may be deposited over the piezoelectric plate. and patterned to define the conductor level. The appropriate conductor layers may be deposited in sequence over the surface of the piezoelectric plate. The photoresist may then be removed, which removes the excess material, leaving the conductor level.

When a conductor level has multiple layers, the layers may be deposited and patterned separately. In particular, different patterning processes (i.e. etching or lift-off) may be used on different layers and/or levels and different masks are required where two or more layers of the same conductor level have different widths or shapes.

At 1040, dielectric layers may be formed by depositing one or more layers of dielectric material on the front side of the piezoelectric plate. As previously described, the dielectric layers may include a different dielectric thickness over the IDT fingers of the XBARs within each sub-filter. Each dielectric layer may be deposited using a conventional deposition technique such as sputtering, evaporation, or chemical vapor deposition. Each dielectric layer may be deposited over the entire surface of the piezoelectric plate, including on top of the conductor pattern. Alternatively, one or more lithography processes (using photomasks) may be used to limit the deposition of the dielectric layers to selected areas of the piezoelectric plate, such as only between the interleaved fingers of the IDTs. Masks may also be used to allow deposition of different thicknesses of dielectric materials on different portions of the piezoelectric plate.

In a second variation of the process 1000, one or more cavities in the form of recesses in the IPD layer may be formed at 1010B by etching the IPD layer using an etchant introduced through openings in the piezoelectric plate. A separate cavity may be formed for each resonator in a filter device.

In all variations of the process 1000, the filter device is completed at 1060. Actions that may occur at 1060 include forming structural supports such as ribs on the piezoelectric plate or the IPD layer, forming a lid on the device for protection and insulation, depositing an encapsulation/passivation layer such as SiO₂ or Si₃O₄ over all or a portion of the device; forming bonding pads or solder bumps or other means for making connection between the device and external circuitry; excising individual devices from a wafer containing multiple devices; other packaging steps; and testing. Another action that may occur at 1060 is to tune the resonant frequencies of the resonators within the device by adding or removing metal or dielectric material from the front side of the device. After the filter device is completed, the process ends at 1095.

### CLOSING COMMENTS

Throughout this description, the embodiments and examples shown should be considered as exemplars, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

It is claimed:

1. An acoustic resonator device comprising:
a piezoelectric plate, wherein a portion of the piezoelectric plate forms a diaphragm that spans a cavity;
an interdigital transducer (IDT) formed on a front surface of the piezoelectric plate such that interleaved fingers of the IDT are disposed on the diaphragm; and
an integrated passive device circuit (IPD) connected to the IDT.

2. The device of claim 1 further comprising a substrate, wherein the piezoelectric plate is mounted on the substrate and the substrate is disposed on the IPD.

3. The device of claim 1 further comprising a substrate, wherein the piezoelectric plate is mounted on the substrate and the substrate is disposed adjacent to the IPD on a circuit board.

4. The device of claim 1, wherein the piezoelectric plate is mounted on and integrated into the IPD.

5. The device of claim 4, wherein the IPD comprises a spiral inductor.

6. The device of claim 5, wherein the spiral inductor comprises copper.

7. The device of claim 1, wherein the IPD comprises a metal-insulator-metal (MIM) capacitor.

8. The device of claim 1, wherein the piezoelectric plate comprises lithium niobate or lithium tantalate.

9. A filter device comprising:
a piezoelectric plate, wherein portions of the piezoelectric plate form diaphragms that spans respective cavities;
a conductor pattern formed on a front surface of the piezoelectric plate, the conductor pattern comprising a plurality of interdigital transducers (IDTs) of a respective plurality of resonators, interleaved fingers each IDT disposed on respective diaphragm of the plurality of diaphragms; and
an integrated passive device circuit (IPD) connected to the plurality of IDTs.

10. The device of claim 9 further comprising a substrate, wherein the piezoelectric plate is mounted on the substrate and the substrate is disposed on the IPD.

11. The device of claim 9 further comprising a substrate, wherein the piezoelectric plate is mounted on the substrate and the substrate is disposed adjacent to the IPD on a circuit board.

12. The device of claim 9, wherein the piezoelectric plate is mounted on and integrated into the IPD.

13. The device of claim 12, wherein the IPD comprises a spiral inductor.

14. The device of claim 13, wherein the spiral inductor comprises copper.

15. The device of claim 9, wherein the IPD comprises a metal-insulator-metal (MIM) capacitor.

16. The device of claim 9, wherein the piezoelectric plate comprises lithium niobate or lithium tantalate.

17. A method of making an acoustic resonator device comprising:
forming an interdigital transducer (IDT) formed on a front surface of a piezoelectric plate such that interleaved fingers of the IDT are disposed on a portion of the piezoelectric plate forming a diaphragm that spans a cavity; and
connecting an integrated passive device circuit (IPD) to the IDT.

18. The method of claim 17, wherein the piezoelectric plate is mounted on the substrate and the substrate is disposed on the IPD.

19. The method of claim 17, wherein the piezoelectric plate is mounted on the substrate and the substrate is disposed adjacent to the IPD on a circuit board.

20. The method of claim 17, wherein the piezoelectric plate is mounted on and integrated into the IPD.
